(19) United States
(12) Patent Application Publication
(10) Pub. No.: US 2021/0118248 A1
(43) Pub. Date: Apr. 22, 2021

(54) METHODS AND SYSTEMS FOR CONTINUOUSLY DETERMINING REMAINING USEFUL LIVES OF VEHICLE COMPONENTS

(71) Applicant: The Boeing Company, Chicago, IL (US)

(72) Inventors: Charles E. Martin, Santa Monica, CA (US); Jaehoon Choe, Malibu, CA (US); Alexander N. Waagen, Malibu, CA (US); Tsai-Ching Lu, Malibu, CA (US); Matt E. Bergsman, Mesa, AZ (US); James J. Tusick, Mesa, AZ (US)

(73) Assignee: The Boeing Company, Chicago, IL (US)

(21) Appl. No.: 16/654,986

(22) Filed: Oct. 16, 2019

(51) Int. Cl. G07C 5/08; G06F 17/50

(52) U.S. Cl. CPC G07C 5/085; G06Q 30/0635; G06F 17/5009

(57) ABSTRACT

Disclosed are methods and systems for continuously determining remaining useful lives (RULs) of vehicle components during operation of these vehicles. A method involves obtaining reference sensor data as well as operational sensor data (both of which are multidimensional) and constructing distributions of these respective data sets. The operational sensor data is obtained from a plurality of sensors, operationally coupled to a vehicle component and continuously obtaining real-time characteristics of this component. The reference sensor data is obtained, in some examples, from a database for equivalent components, long before the end of life or required replacements. Sliced-Wasserstein distances are computed between these distributions and early notification signals (ENS) are determined on these distances. Finally, a RUL of the vehicle component is determined based on the ENS using a RUL model. In some examples, the RUL model is selected from multiple RUL models, which are dynamically developed during operation of the vehicle.

### BACKGROUND

Various approaches have been used for determining remaining useful lives (RULs) of vehicle components and detecting anomalies in generated sensor data. Typically, the anomaly detection involves finding various sensor data patterns that do not conform to expected behavior, which may be referred to as baseline data. In the past, regression models and other like statistical tools have been used for this anomaly detection. However, these conventional approaches are generally limited to normal operating conditions and are not sufficiently versatile to account for variations in operating conditions. Another approach is clustering analysis. However, the clustering analysis typically discards useful temporal information. Further, all of these methods need a large parameter space, requiring considerable efforts to identify various settings and parameters during data analysis.

What is needed are new methods and systems for continuously determining remaining useful lives (RULs) of vehicle components during operation of these vehicles.

### SUMMARY

Disclosed are methods and systems for continuously determining remaining useful lives (RULs) of vehicle components during operation of these vehicles. A method involves obtaining reference sensor data as well as operational sensor data (both of which are multidimensional) and constructing distributions of these respective data sets. The operational sensor data is obtained from a plurality of sensors, operationally coupled to a vehicle component and continuously obtaining real-time characteristics of this component. The reference sensor data is obtained, in some examples, from a database for equivalent components, long before the end of life or required replacements. Sliced-Wasserstein distances are computed between these distributions and early notification signals (ENS) are determined on these distances. Finally, a RUL of the vehicle component is determined based on the ENS using a RUL model. In some examples, the RUL model is selected from multiple RUL models, which are dynamically developed during operation of the vehicle.

A method for continuously determining a RUL of a component on a vehicle during operation of the vehicle is described. The method comprises obtaining reference sensor data, corresponding to the component of the vehicle, wherein the reference sensor data is multidimensional. The method also comprises obtaining operational sensor data from a plurality of sensors, operationally coupled to the component of the vehicle, wherein the operational sensor data is multidimensional. The method further comprises constructing reference sensor data distribution, using the reference sensor data. The method comprises constructing operational sensor data distribution, using the operational sensor data. The method also comprises computing sliced-Wasserstein distances between the reference sensor data distribution and the operational sensor data distribution. The method further comprises determining ENS based on the sliced-Wasserstein distances and determining the RUL of the component on the vehicle based on the ENS using a RUL model.

A system for determining a RUL of a component on a vehicle during operation of the vehicle is described. The system comprises a database, comprising reference sensor data, corresponding to the component of the vehicle, wherein the reference sensor data is multidimensional. The system also comprises a RUL module, communicatively coupled to the database and configured to obtain the reference sensor data from the database. The RUL module is further configured to obtain operational sensor data from a plurality of sensors, operationally coupled to the component of the vehicle, wherein the operational sensor data is multidimensional, construct reference sensor data distribution, using the reference sensor data, construct operational sensor data distribution, using the operational sensor data, compute sliced-Wasserstein distances between the reference sensor data distribution and the operational sensor data distribution, determine ENS based on the sliced-Wasserstein distances, and determine the RUL of the component on the vehicle based on the ENS using a RUL model.

A computer-readable medium including instructions, which when executed by a RUL module, operably coupled to a component on a vehicle during operation of the vehicle, cause the RUL module, to perform operations, in described. The operations comprise obtaining reference sensor data, corresponding to the component of the vehicle, wherein the reference sensor data is multidimensional. The operations also comprise obtaining operational sensor data from a plurality of sensors, operationally coupled to the component of the vehicle, wherein the operational sensor data is multidimensional. The operations further comprise constructing reference sensor data distribution, using the reference sensor data, constructing operational sensor data distribution, using the operational sensor data, computing sliced-Wasserstein distances between the reference sensor data distribution and the operational sensor data distribution, determining ENS based on the sliced-Wasserstein distances, and determining RUL of the component on the vehicle based on the ENS using a RUL model.

### BRIEF DESCRIPTION OF THE DRAWINGS

FIG. 1 is a block diagram representing a system for determining RUL of a vehicle component during operation of the vehicle, in accordance with some examples.

FIG. 2 is a process flowchart corresponding to a method for determining RUL of a vehicle component during operation of the vehicle, in accordance with some examples.

FIG. 3 is a histogram, illustrating one illustrative relationship between RUL and ENS.

FIG. 4 is a scatterplot, illustrating one illustrative relationship between RUL and ENS.

FIG. 5 is an example of a table, representing different RUL models, each model corresponding to different RUL and ENS intervals.

FIG. 6 is a block diagram of a computer system, operable as a RUL module, in accordance with some examples.

FIG. 7 is a process flowchart corresponding to a method for manufacturing and service the aircraft, utilizing various aspects of determining RULs of vehicle components, in accordance with some examples.

FIG. 8 illustrates a block diagram of an example of an aircraft, in accordance with some examples, in accordance with some examples.

### DETAILED DESCRIPTION

In the following description, numerous specific details are set forth in order to provide a thorough understanding of the presented concepts. In some examples, the presented concepts are practiced without some or all of these specific details. In other instances, well known process operations have not been described in detail so as to not unnecessarily obscure the described concepts. While some concepts will be described in conjunction with the specific examples, it will be understood that these examples are not intended to be limiting.

### Introduction

Accurate estimates of RULs of various vehicle components can be challenging. For example, operational data, obtained from sensors coupled to these components, often have various limitations and constraints, such as data sparsity, unexpected signal properties, and the like. Analyses performed post-hoc or offline are of little use for predictive analytics and logistics that, for example, need some lead time for scheduling maintenance and/or procuring replacement parts. Furthermore, conventional methods tend to use static predictive models, which are not sufficiently accurate, especially considering diversity and limitations of the sensor data. Overall, the accuracy and robustness of prediction capabilities have not been adequately demonstrated using conventional methods and systems.

Novel methods and systems, described herein, utilize operational sensor data to provide accurate and continuous forecasts of component RULs on various types of vehicles. These methods and systems uncover and provide previously invisible information about the state (aka “health”) of individual vehicle components (e.g., a nose gearbox in a rotorcraft). Furthermore, these methods and systems allow maintenance personnel to replace and/or repair these components before their end of life thereby reducing vehicle downtime and unexpected shutdowns, both of which are highly undesirable.

Unlike conventional machine-learning driven predictive systems, the methods and systems described herein are able to operate with limited training data by (1) continuous computation of ENS and by (2) dynamically developing competing RUL models, which are evaluated against one another using permutative simulation. This evaluation provides direct metrics of accuracy for specific forecast measures and objective comparison of all developed RUL models, while selecting one for the actual use for determining the component RUL. The permutative simulation is also useful in scenarios when ground-truth data is sparse, e.g., sensor data collected from components corresponding to the end of life is limited. Furthermore, the methods and systems described herein conform to the unique temporal properties of the sensor data, utilizing the transience or persistence of anomalous activity as part of the derivation of the ENS signal. For example, an ENS is computed using a RUL model based on historical sensor data and ground-truth ends of life. As such, the method incorporates a well-grounded baseline that differentiates between diverse normal conditions and true end-of-life conditions. This feature, in turn, allows avoiding false positives. Furthermore, this feature mitigates inherent difficulties in processing sensor data, which is sometimes interspersed with temporarily aberrant signals that do not serve as reliable end-of-life markers, e.g., during vehicle operation.

Methods and systems, described herein, include various features to overcome challenges, associated with conventional methods listed above. For example, ENS is determined based on sliced-Wasserstein distances. This approach allows for dimensionality reduction for sensor datasets. Specifically, multiple different types of sensor data, which may be also referred to as condition indicator signals or, simply, condition indicators (Cis), are fused together using sliced-Wasserstein distances to generate one-dimensional ENS output. This approach is computationally efficient, robust, and theoretically grounded. At the same time, utilizing multiple different types of sensor data provides stronger ENS by quantifying signal correlations. Furthermore, multiple RUL models are dynamically developed and checked for robustness and generalizability. Each RUL model is associated with corresponding precision values such that each one of these precision values corresponds to a unique combination of one of multiple RUL intervals and one of multiple ENS intervals. One model is then selected for determined the component RUL based on the ENS, e.g., the model with the highest precision value for the RUL and ENS intervals in question. Also, large amounts of data, prior to the end of life, is leveraged based on establish a baseline data, which may be referred to as reference sensor data. Newly collected data is referred to as operational sensor data. Overall, these methods and systems reduce time and effort needed to build RUL models from sensor data, require fewer examples of end of life to build predictive models, and go beyond predicting the end of life while providing robust estimates of components' RULs.

These methods and systems provide prognostics and health management of various components and, in some examples, are used for logistics and supply-chain support of various types of vehicles (e.g., rotorcraft). It should be noted that supply-chain support can be particularly important when vehicles are deployed in remote areas with limited access. Having foreknowledge of components' RULs allow fleet managers and local maintenance personnel to procure replacement parts ahead of time, allocate resources for service and repair, and/or to move vehicles to maintenance centers, while the vehicles are still operational.

### System Examples

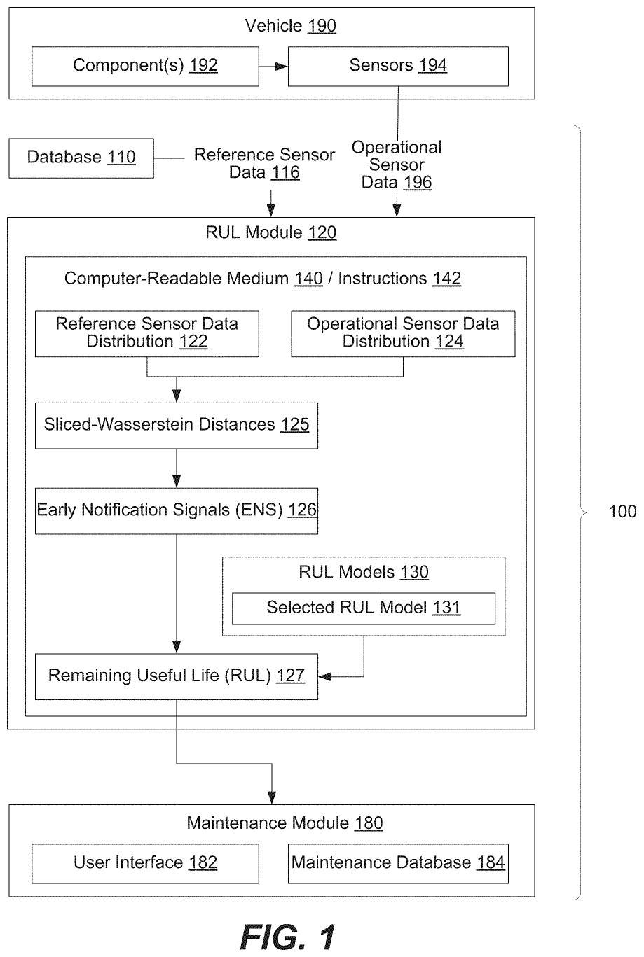

FIG. 1 is schematic illustration of system 100 for determining RUL 127 of component 192 on vehicle 190, in accordance with some examples. System 100 is configured for continuous real-time determination of RUL 127, while vehicle 190 is in operation. In some examples, system 100 is a part of vehicle 190, e.g., a part of a controller area network (CAN) on a car. Alternatively, system 100 is a separate unit from vehicle 190, in which case, system 100 is communicatively coupled with vehicle 190.

Various examples of vehicle 190 are within the scope of this disclosure, e.g., a rotorcraft, a fixed-wing aircraft, an automobile, and the like. In some examples, one system 100 supports multiple vehicles, which may be the same type vehicles or different type vehicles. Alternatively, each vehicle 190 has a dedicated system, e.g., an onboard system.

Vehicle 190 comprises one or more components, at least one of which, e.g. component 192, is monitored by system 100 to determine RUL 127 of this component. In some examples, system 100 is configured to simultaneous monitored multiple components of the same vehicle or multiple vehicles (e.g., the same type components across a fleet of vehicle). Some examples of component 192 include, but are not limited to, a nose gearbox of a rotorcraft, an engine, and a rotor.

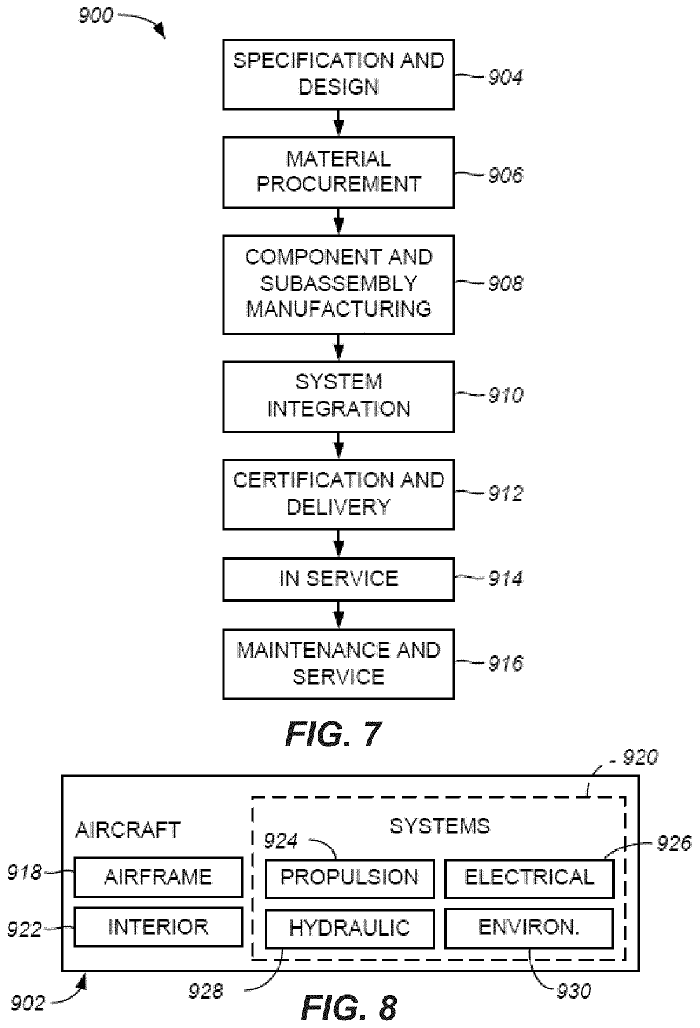

Vehicle 190 also comprises plurality of sensors 194, operationally coupled to component 192. Some examples of such sensors include, but are not limited to, an accelerometer, a temperature sensor, a pressure sensor, a voltmeter, an electrical current meter, and an acoustic sensor. Plurality of sensors 194 is configured to generate operational sensor data 196, associated with the current state of component 192. Operational sensor data 196 is generated during operation of vehicle 190 or, more specifically, during operation of component 192. Operational sensor data 196 should be distinguished from reference sensor data 116, described below. Additional features of vehicles are described below with reference to FIGS. 7 and 8.

Returning to FIG. 1, system 100 comprises RUL module 120, which is operationally or communicatively coupled to plurality of sensors 194 and configured to receive operational sensor data 196 from plurality of sensors 194. This coupling is, for example, direct wired or wireless coupling, network coupling, and the like. The coupling ensures that operational sensor data 196 is received (immediately or with a minimal delay) by RUL module 120 after operational sensor data 196 is generated by plurality of sensors 194. In some examples, plurality of sensors 194 are configured to store operational sensor data 196 for sending to RUL module 120, e.g., at a later time when the coupling between RUL module 120 and plurality of sensors 194 is unavailable.

RUL module 120 is also operationally or communicatively coupled to database 110 and configured to receive reference sensor data 116 from database 110. This coupling is, for example, direct wired or wireless coupling, network coupling, and the like. This coupling ensures that reference sensor data 116 is received by RUL module 120. In some embodiments, database 110 is part of RUL module 120.

Unlike operational sensor data 196, which is received and processed by RUL module 120 in real time (during operation of component 192), reference sensor data 116 is gathered earlier from the same component or other components and/or vehicles. In some examples, reference sensor data 116 is filtered prior to supplying to RUL module 120 and/or storing in database 110. For example, reference sensor data 116, after filtering, represents RUL 127 of one or more components that exceed a certain minimum threshold, e.g., away from the end-of-life point. Other data (representing RUL 127 that does not exceed this minimum threshold) is not selected.

Both operational sensor data 196 and reference sensor data 116 are multidimensional. In other words, operational sensor data 196 and reference sensor data 116 represent multiple different characteristics of component 192, e.g., a combination of accelerations (direction and magnitude), temperature, pressure, voltage, electrical current, and acoustic signal (frequency, sound pressure level), and the like. The multidimensional feature improves the precision during estimates of RUL 127.

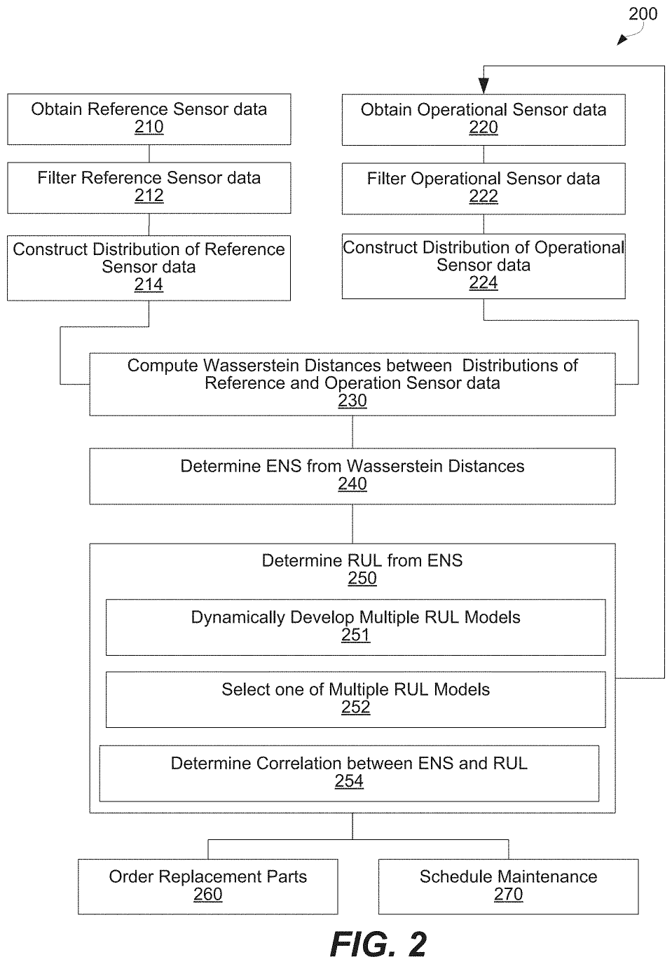

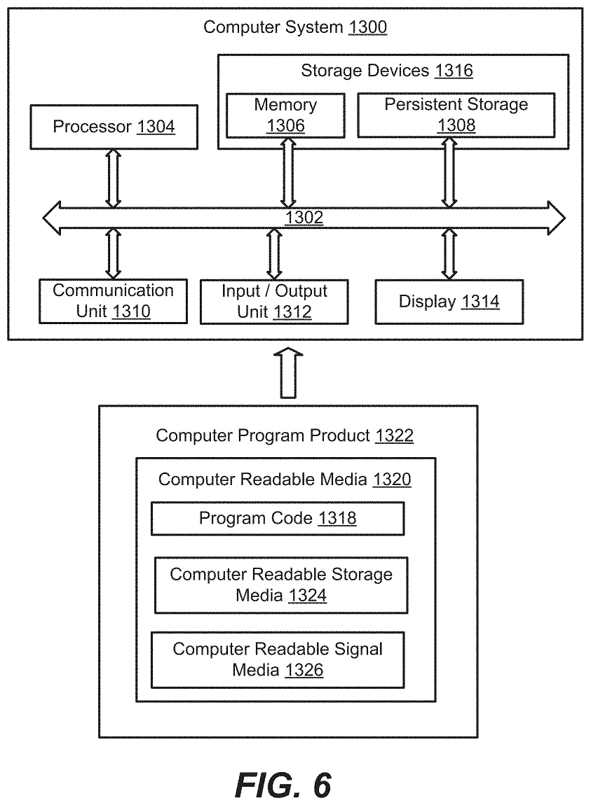

In some examples, RUL module 120 is a computer system, various examples and features of which are described below with reference to FIG. 6. Furthermore, RUL module 120 is configured to perform various operations, described below with reference to FIG. 2, and eventually determine RUL 127 of component 192 based on operational sensor data 196 and reference sensor data 116. Specifically, RUL module 120 is configured to obtain reference sensor data 116, obtain operational sensor data 196, construct reference sensor data distribution 122, construct operational sensor data distribution 124, compute sliced-Wasserstein distances 125 between reference sensor data distribution 122 and operational sensor data distribution 124, determine ENS 126 based on sliced-Wasserstein distances 125, and determine RUL 127 of component 192 based on ENS 126 using RUL model 131. In some examples, RUL module 120 is also configured to dynamically develop multiple RUL models 130 and select RUL model 131 (for the actual use in determining RUL 127 of component 192) from these multiple RUL models 130. Furthermore, in some example, RUL module 120 is configured to communicate RUL 127 of component 192 to maintenance module 180, which is used by maintenance personnel of vehicle 190.

Referring to FIG. 1, maintenance module 180 is a part of system 100 or at least communicatively coupled to system 100 or, more specifically, to RUL module 120 of system 100. In some examples, maintenance module 180 is equipped with user interface 182 (e.g., for displaying RUL 127 to maintenance personnel) and/or maintenance database 184 (e.g., for storing RUL 127).

In some examples, RUL module 120 comprises computer-readable medium 140. Computer-readable medium 140 may take various forms described below with reference to FIG. 6. Computer-readable medium 140 includes instructions 142, which when executed by RUL module 120, causes RUL module 120 various operations of method 200, describe below with reference to FIG. 2.

### Method Examples

FIG. 2 is a flowchart corresponding to method 200 for continuously determining RUL 127 of component 192 on vehicle 190, in accordance with some examples. Various examples of component 192 and examples of vehicle 190 are described above with reference to FIG. 1. Furthermore, various operations of method 200 are performed by system 100, which is also described above with reference to FIG. 1.

In some examples, method 200 involves obtaining reference sensor data 116 (block 210). Reference sensor data 116 corresponds to component 192 and is multidimensional. For example, reference sensor data 116 represents a combination of different reference characteristics of component 192, such as reference acceleration (magnitude and direction), reference temperature, reference pressure, reference resistance/voltage/current, reference acoustic signal, and the like. In some examples, reference sensor data 116 is obtained, e.g., prior to initiation of method 200, using sensors of corresponding vehicles, e.g., accelerometers, azimuth sensors, microphones, temperature proves, optical trackers, and the like. Furthermore, in some examples, reference sensor data 116 is updated/added to during execution of method 200. For example, at least some of operational sensor data 196 is added to reference sensor data 116 after operational sensor data 196 is processed by RUL module 120, as further described below.

Overall, reference sensor data 116 represent a set of condition indicators, measured or otherwise obtained for a group of vehicles, equivalent to vehicle 190 (e.g., being the same or similar vehicle model). Reference sensor data 116 is obtained prior one or more target components reaching the RUL and needing to be removed. For example, reference sensor data 116 represents various historical data collected from vehicles during normal operating conditions, before the end of life of one or more target components. In some examples, reference sensor data 116 does not include any outlier measurements.

Method 200 proceeds with obtaining operational sensor data 196 (block 220). Specifically, operational sensor data 196 is obtained by RUL module 120 from plurality of sensors 194, operationally coupled to component 192 of vehicle 190. In some examples, vehicle 190 is a part of a group of vehicles that are being monitored simultaneously. Operational sensor data 196 represents current operation characteristics of component 192 and, depending on RUL 127, reflects normal operation and/or abnormal operation (e.g., near replacement or repair of component 192). Specifically, operational sensor data 196 corresponding to RUL 127 above a certain threshold represents normal operation, while operational sensor data 196 corresponding to RUL 127 below that threshold represents abnormal operation.

In some examples, operational sensor data 196 is collected throughout the entire operating life of component 192. Alternatively, various trigger points are used to initiate collections of operational sensor data 196, e.g., after 50% of the operating life has passed/RUL 127 below a certain threshold, at certain sensor conditions, and the like. In some examples, operational sensor data 196 is collected at one or more particular operating conditions of vehicle 190 (e.g., when the blades of a rotorcraft are flat-pitched at 100% rotation rate) to ensure correspondence with reference sensor data 116.

In some examples, method 200 involves filtering reference sensor data 116 (block 212). For example, reference sensor data 116 corresponding to one or more components is excluded due to insufficient amount of the data for these components (e.g., components have not previously reached the end of useful life), not associated with the relevant components or vehicles, and other like criteria. Overall, once sufficient amount of operational sensor data 196 is collected, each monitored component is represented by corresponding reference sensor data. It should be noted that various latent environmental factors and operational parameters are able to impact reference sensor data, which make the process of finding strong signals in this data more challenging. To address this challenge, various portions of reference sensor data is automatically grouped using simulated annealing. Simulated annealing is used to compute the global optimum of a function in a large search space, presented by various sensor data/condition indicators. It has been found that the end of life in various types of vehicles (e.g., rotorcraft) tend to converge toward a particular mode. As such, simulated annealing allows grouping and identifying archetypes of the end of life. Furthermore, simulated annealing allows categorizing and increasing the confidence of end-of-life forecasts. In some examples, simulated annealing is used for finding a group of components/vehicles and a group of associated sensor data/condition indicators that maximize the signal, e.g., as determined by a defined objective function (further described below) and subject to specified constraints. In other words, vehicles are grouped to maximize signal and not based on direct comparison of features.

In some examples, method 200 also involves filtering operational sensor data 196 (block 222). This operation is similar to the one described above with reference to block 212.

Method 200 proceeds with constructing reference sensor data distribution 122 (block 214). Reference sensor data distribution 122 is constructed from reference sensor data 116, which in some examples is first filtered as described above. Reference sensor data distribution 122 is a multivariate distribution, called the base distribution, which is later compared to the empirical distribution formed by a current sequence of sensor measurements using the Sliced-Wasserstein distance. The comparison between the base distribution and the current distribution consists of computing the distance between them using the Sliced-Wasserstein distance, as further described below.

Method 200 also involves constructing operational sensor data distribution 124 (block 224). Operational sensor data distribution 124 is constructed from operational sensor data 196, which in some examples is first filtered as described above. Operational sensor data distribution 124 is a multivariate distribution, which is later used to form a base distribution using sliced-Wasserstein distances.

Method 200 proceeds with computing sliced-Wasserstein distances 125 between reference sensor data distribution 122 and operational sensor data distribution 124 (block 230). This operation provides a computationally efficient way of analyzing operational sensor data 196, based on reference sensor data 116, to determining ENS 126 and, later, to determine RUL 127.

A Wasserstein distance is effectively a similarity metric between two separate probability distributions, which are reference sensor data distribution 122 and operational sensor data distribution 124. In other words, the Wasserstein distance measures the “effort” necessary to change one distribution to another, which produces distance scores even if isolated deviant signals only appear sporadically. With this approach, distance scores may be computed on any probability distribution, one of each dimension, providing more granular view of component 192. The robustness is further increased by slicing each of reference sensor data distribution 122 and operational sensor data distribution 124 and computing separate Wasserstein distances for comparing temporal slices. One slice, which may be referred to as a baseline, is computed in ongoing fashion from reference sensor data distribution 122. The second slice is the most recent version of operational sensor data distribution 124 is used. This feature allows the clear observation of anomalous activity that incorporates, yet deemphasizes, historical, transient outlier data. Lower Wasserstein distances indicate that the two distributions are similar, while large Wasserstein values indicate that the two distributions are more dissimilar.

Overall, computing sliced-Wasserstein distances 125 works particularly well for highly dimensional data (e.g., data with 20-30 dimensions obtained by multiple sensors). The approach is based on taking one-dimensional “slices” and projecting reference sensor data 116 and operational sensor data 196 on each one of these one-dimensional slices. The difference between reference sensor data 116 and operational sensor data 196 in each one-dimensional slice is determined and then the mean of these differences across different slices.

Method 200 proceeds with determining ENS 126 from sliced-Wasserstein distances 125 (block 240). Sliced-Wasserstein distances 125 provide indication of ENS 126 for component 192. In some examples, this ENS 126 is also referred to as Wasserstein ENS. In general, larger Wasserstein distances correspond to stronger ENS 126 and shorter RULs.

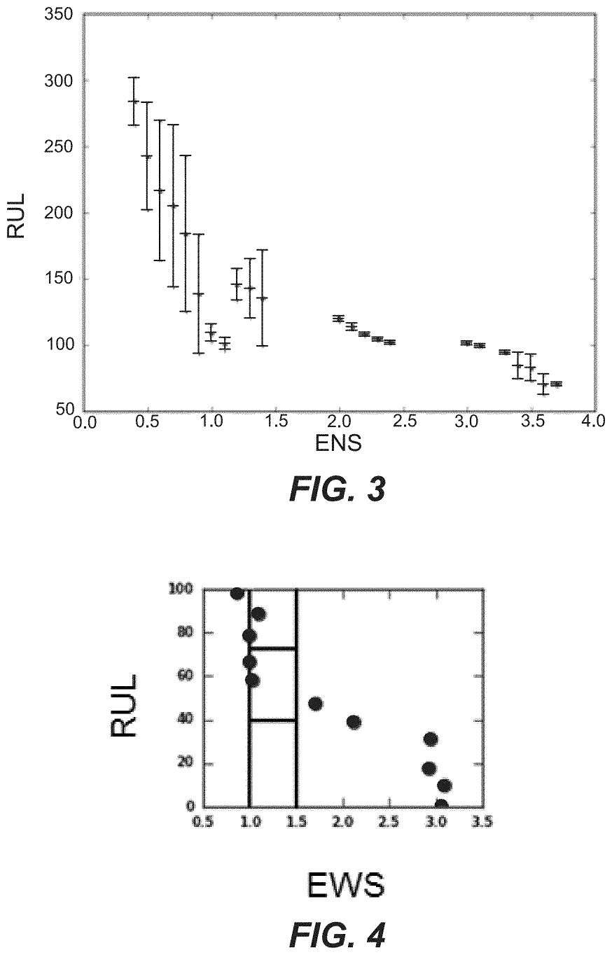

Method 200 proceeds with determining RUL 127 from ENS 126 using RUL model 131 (block 250). In some examples, the relationship between RUL 127 and ENS 126 is visualized using a histogram, one example of which is presented in FIG. 3. Specifically, the histogram is used to determine the overall signal strength of ENS 126, which is computed from the Wasserstein distances by specifying the constraint, e.g., C(1,1,1)>1.5. For each ENS value (on the X axis), a corresponding RUL value (on the Y axis) is identified by the point. Furthermore, the histogram identifies a confidence interval, represented by one standard deviation from the mean and identified with error bars. Portions of the histogram with stronger relationship between RUL 127 and ENS 126 have smaller error bars.

The strength of the signal is based on two features. The first feature is a normalized dot product of the RUL values and corresponding mean ENS value, which is the cosine of the angle between these vectors. Smaller values correspond to more negative correlation between these two vectors. The second feature is a mean error ratio defined as the standard deviation divided by remaining useful life. For example, if the standard deviation is 50 and the remaining useful life is 100, the error ratio at that time for that vehicle is 0.5. The range variance is defined as the standard deviation of the minimum ENS values of the vehicles added to the standard deviation of the maximum values of the vehicles. Keeping this value small causes the range of ENS signals of the collection of chosen vehicles to be similar across all vehicles. The normalized dot product is referred as δ (delta), the mean error ratio as ε (epsilon), range the range variance as γ (gamma). Note that the normalized dot product δ is minimized at 0.5 and the mean error ratio ε and range variance γ are minimized at 0.0. The constraint function C(A,B,C) is defined using the following formula:

C(A,B,C)=A(−ε)+B(0.5−δ)+C(−γ) (Formula 1)

In this formula, A, B, and C are positive numbers specifying how much each aspect should be emphasized. A value M in C (A, B, C)>M is also specified to accept a change to the input. In some embodiments, the process loops over many possible combinations of coefficients A, B, and C to determine the effect of the constraint function specified. In particular, all possible combinations of A, B, and C are checked, using the coefficients 0 and 1 with M=1.5.

In some examples, training data is limited. For example, vehicles may have limited repair history (e.g., newer vehicles) or many sources of variability (e.g., noise) were present during data collection. In these examples, identifying a robust function that maps any ENS values to a narrow (e.g., +/−50%) range of RUL values is not always possible. As such, in these examples, simulated annealing is applied to identify a sub-group of vehicles and corresponding sensor data (condition indicators) for which the ENS signal is particularly strong inside that RUL interval, but not necessarily anywhere else. In some example, a higher ENS value does not correspond to a lower RUL value. Instead, ENS 126 behaves differently inside that interval, in comparison to outside that interval. These examples are illustrated in a scattered plot in FIG. 4. Specifically, in this scattered plot, each data point corresponds to an individual vehicle and time. The vertical lines in FIG. 4 represent the period of time during which the remaining useful life is between 100 and 150. The horizontal lines represent the ENS values identified as having the strongest signal. The strength of the signal inside the box is the precision of the model which outputs the RUL interval (40, 70) whenever the ENS is between 1.0 and 1.5 as in FIG. 4. The precision is the probability that if a point is observed with the ENS value in the interval (1, 1.5) the RUL value is within the RUL interval (40, 70). That is, it is the number of points lying inside the box in the center divided by the total number of points lying inside the two vertical bars.

In some examples, method 200 involves dynamically developing multiple RUL models 130 (block 251) and selecting RUL model 131 from multiple RUL models 130 (block 252). Each selection of sensors and subgroups of vehicles results in a different RUL model. Simulated annealing is applied to make gradual changes to the selected sensor data and the selected vehicles, there resulting in new RUL models.

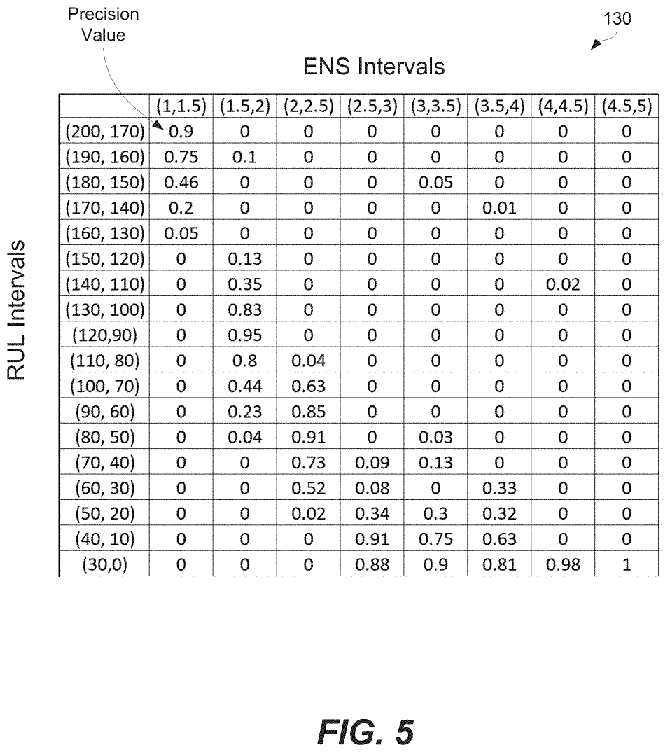

Referring to the operation represented by block 252, FIG. 5, in some examples, each of multiple RUL models 130 corresponds to a unique combination of one of multiple RUL intervals and one of multiple ENS intervals. Furthermore, each of multiple RUL models 130 has a corresponding one of precision values. Specifically, the columns represent ENS intervals, while the rows represent RUL intervals. Each entry in the matrix, shown in FIG. 5, represents a different one of multiple RUL models 130, i.e., a RUL model that predicts that a precision value of the specified RUL interval in the provided ENS interval. For example, if ENS 126 has a value in the 1.0-1.5 interval, then the most observable RUL (i.e., the RUL interval with the highest precision value) is within the 170-200 interval. In some examples, RUL model 131 is selected based on the highest precision values for the determined ENS value (or the interval including the determined ENS value).

In some examples, method 200 involves cross-validating selected models (block 254). Specifically, cross-validation is used for testing the ability of a learned model to make correct/accurate predictions on new data points. One example is leave-one-out cross-validation, which is performed by (1) removing a single data point from a data set, (2) training the model on the remaining data, and (3) testing the trained model on the point that was removed. This procedure is repeated for each individual data point in the data set, and the prediction metrics for all data points are averaged and recorded in a table or a heat map. The prediction metrics is developed for each model in a model set. One model is then selected from the model set based in the prediction metrics, e.g., the highest prediction value in a particular ENS range. For example, the cross-validation is used for determining each of the precision values described above with reference to block 252 and FIG. 5.

In some examples, permutative simulation is used for selecting RUL model 131. Specifically, for each individual vehicle, ENS are computed using Wasserstein distances, which yields an ENS value corresponding to each RUL, to build multiple RUL models 130, as described earlier. Having built each of multiple RUL models 130 and scored each using cross validation, simulated annealing is used to make slight changes to the subgroup of vehicle selected as well as the sensors selected such that a new RUL model is built.

In some example, at least obtaining operational sensor data 196 (block 220), constructing operational sensor data distribution 124 (block 224), computing sliced-Wasserstein distances 125 (block 230), and determining ENS 126 (block 240) is performed continuously during operation of vehicle 190 as schematically shown in FIG. 2 by a return arrow.

In some examples, method 200 further comprises performing at least one of ordering (block 260) one or more replacement parts for component 192 based on RUL 127 or scheduling (block 270) maintenance of vehicle 190 based on RUL 127. Both of these operations are performable while vehicle 190 remains in service and is operational (e.g., RUL 127 is greater than zero). In other words, these operations are performed prior to the end of life of component 192. Furthermore, the frequency of ordering one or more replacement parts for component 192 or scheduling maintenance of vehicle 190 varies, in some examples. In other words, operations represented by block 260 and 270 are not parts of the scheduled periodic maintenance of vehicle 190 but rather as needed/just-in-time types of processes. In some examples, the value of RUL 127 is used to prioritize these operations, e.g., expedite if the value of RUL 127 is small. Furthermore, in some examples, RUL 127 is sent to maintenance module 180 (e.g., used by the maintenance personnel to order parts and schedule maintenance). More specifically, RUL 127 is displayed on maintenance module 180 (e.g., on user interface 182 of maintenance module 180) and, in some examples, is stored in maintenance database 184 for future use, e.g., trending, further analysis.

### Computer System Examples

FIG. 5 illustrates computer system 1300 and computer program product 1322, configured in accordance with some examples. Various components of RUL module 120, computer-readable medium 140, and instructions 142, described above with reference to FIG. 1 are implementable as and supportable by components of computer system 1300 and computer program product 1322.

In various examples, computer system 1300 includes communications framework 1302, which provides communications between processor unit 1304, memory 1306, persistent storage 1308, communication unit 1310, input/output unit 1312, and display 1314. In this example, communications framework 1302 takes form of a bus system.

Processor unit 1304 serves to execute instructions for software (e.g., computer-readable medium 140 or, at least, instructions 142) that is loaded into memory 1306. Memory 1306 and persistent storage 1308 are examples of storage devices 1316/computer-readable medium 140. A storage device is any piece of hardware capable of storing information, such as, for example, without limitation, data, program code in functional form, and/or other suitable information either on a temporary basis and/or a permanent basis. Storage devices 1316 are also referred to as computer readable storage devices in these illustrative examples. Memory 1306, in these examples, is a random access memory or any other suitable volatile or non-volatile storage device. Persistent storage 1308 takes various forms, depending on implementation. For example, persistent storage 1308 may be a hard drive, a flash memory, a rewritable optical disk, a rewritable magnetic tape, or some combination of above. Media used by persistent storage 1308 is removable, in some examples.

Communications unit 1310, in these illustrative examples, provides for communications with other computer systems or devices. In these illustrative examples, communications unit 1310 is a network interface card, universal serial bus (USB) interface, or other suitable communications device/interface.

Input/output unit 1312 allows for input and output of data with other devices that are connected to computer system 1300. For example, input/output unit 1312 provides a connection for user input through a keyboard, a mouse, and/or some other suitable input device. Further, input/output unit 1312 sends output to a printer. Display 1314 provides a mechanism to display information to a user.

In some examples, instructions for an operating system, applications, and/or programs are located in storage devices 1316, which are in communication with processor unit 1304 through communications framework 1302. Processes of different examples are performed by processor unit 1304 using computer-implemented instructions, which are located in a memory, such as memory 1306.

These instructions are referred to as program code, computer usable program code, or computer readable program code that is read and executed by a processor in processor unit 1304. Program code in different examples is embodied on different physical or computer readable storage media, such as memory 1306 or persistent storage 1308.

Program code 1318 is located in a functional form on computer readable media 1320 that is selectively removable and is loaded onto or transferred to computer system 1300 for execution by processor unit 1304. Program code 1318 and computer readable media 1320 form or provide computer program product 1322 in these illustrative examples. In one example, computer readable media 1320 is or includes computer readable storage media 1324 or computer readable signal media 1326.

In these illustrative examples, computer readable storage media 1324 is a physical or tangible storage device used to store program code 1318 rather than a medium that propagates or transmits program code 1318.

Alternatively, program code 1318 is transferred to computer system 1300 using computer readable signal media 1326. Computer readable signal media 1326 is, for example, a propagated data signal, containing program code 1318. For example, computer readable signal media 1326 is an electromagnetic signal, an optical signal, and/or any other suitable type of signal. These signals are transmitted over communications links, such as wireless communications links, optical fiber cable, coaxial cable, a wire, and/or any other suitable type of communications link.

The different components illustrated for computer system 1300 are not meant to provide architectural limitations to manner in which different examples are implemented. Different illustrative examples are implemented in a computer system including components in addition to and/or in place of those illustrated for computer system 1300. Other components shown in FIG. 5 can be varied from illustrative examples shown.

### Aircraft Examples

In some examples, the apparatus and methods disclosed above are used on aircraft (e.g., rotorcraft) and, more generally, by the aerospace industry. Specifically, the apparatus can be used during fabrication of aircraft as well as during aircraft service and maintenance.

Accordingly, systems apparatus and methods disclosed above are applicable for aircraft manufacturing and service method 900 as shown in FIG. 7 and for aircraft 902 as shown in FIG. 8. Aircraft 902 is referred to as vehicle 190 in the examples presented above, e.g., with reference to FIG. 1. During pre-production, method 900 includes specification and design 904 of aircraft 902 and material procurement 906. During production, component and subassembly manufacturing 908 and system integration 910 of aircraft 902 takes place. Thereafter, aircraft 902 goes through certification and delivery 912 in order to be placed in service 914. While in service by a customer, aircraft 902 is scheduled for routine maintenance and service 916 (which also includes modification, reconfiguration, refurbishment, and so on.

In some examples, each of the processes of method 900 is performed or carried out by a system integrator, a third party, and/or an operator (e.g., a customer. For the purposes of this description, a system integrator may include without limitation any number of aircraft manufacturers and major-system subcontractors; a third party may include without limitation any number of venders, subcontractors, and suppliers; and an operator can be an airline, leasing company, military entity, service organization, and so on.

As shown in FIG. 8, aircraft 902 produced by method 900 includes airframe 918 with plurality of systems 920, and interior 922. Examples of systems 920 include one or more of propulsion system 924, electrical system 926, hydraulic system 928, and environmental system 930. Any number of other systems can be included. Although an aerospace example is shown, the principles of the examples disclosed herein may be applied to other industries, such as the automotive industry.

Apparatus and methods presented herein can be employed during any one or more of the stages of production and method 900. For example, components or subassemblies corresponding to manufacturing 908 are fabricated or manufactured in a manner similar to components or subassemblies produced while aircraft 902 is in service. Also, one or more apparatus examples, method examples, or a combination thereof may be utilized during manufacturing 908 and system integration 910, for example, by substantially expediting assembly of or reducing the cost of an aircraft 902. Similarly, one or more of apparatus examples, method examples, or a combination thereof may be utilized while aircraft 902 is in service, for example and without limitation, to maintenance and service 916.

### Further Examples

Further, the description includes examples according to the following clauses:

Clause 1. Method 200 for continuously determining RUL 127 of component 192 on vehicle 190 during operation of vehicle 190, method 200 comprising:

obtaining reference sensor data 116, corresponding to component 192 of vehicle 190, wherein reference sensor data 116 is multidimensional;

obtaining operational sensor data 196 from plurality of sensors 194, operationally coupled to component 192 of vehicle 190, wherein operational sensor data 196 is multidimensional;

constructing reference sensor data distribution 122, using reference sensor data 116;

constructing operational sensor data distribution 124, using operational sensor data 196;

computing sliced-Wasserstein distances 125 between reference sensor data distribution 122 and operational sensor data distribution 124;

determining ENS 126 based on sliced-Wasserstein distances 125; and

determining RUL 127 of component 192 on vehicle 190 based on ENS 126 using RUL model 131.

Clause 2. Method 200 of clause 1, wherein determining RUL 127 of component 192 on vehicle 190 comprises:

dynamically developing multiple RUL models 130; and

selecting RUL model 131 from multiple RUL models 130 for determining RUL 127 of component 192 on the vehicle 190.

Clause 3. Method 200 of clause 2, wherein selecting RUL model 131 is performed using permutative simulation.

Clause 4. Method 200 of any one of clauses 2-3, wherein each of multiple RUL models 130 corresponds to a different one of multiple RUL intervals and a different one of multiple ENS intervals, and wherein each of multiple RUL models 130 has a corresponding one of precision values.

Clause 5. Method 200 of clause 4, wherein RUL model 131 is selected based on highest of the precision values for ENS 126, determined based on sliced-Wasserstein distances 125 and being within a corresponding one of the multiple ENS intervals.

Clause 6. Method 200 of any one of clauses 4-5, wherein each of the precision values is determined using cross-validation of a corresponding one of multiple RUL models 130.

Clause 7. Method 200 of any one of clauses 1-6, further comprising determining correlation of ENS 126 and RUL 127 using a constraint function based on a normalized dot product, a mean error ratio, and a range variance.

Clause 8. Method 200 of any one of clauses 1-7, wherein at least obtaining operational sensor data 196, constructing operational sensor data distribution 124, computing sliced-Wasserstein distances 125, determining the ENS is performed continuously.

Clause 9. Method 200 of any one of clauses 1-8, wherein operational sensor data 196 is a fixed-size set of most recent sensor data.

Clause 10. Method 200 of any one of clauses 1-9, wherein sliced-Wasserstein distances 125 are one-dimensional.

Clause 11. Method 200 of any one of clauses 1-10, wherein ENS 126 comprises one or more of end-of-life time of component 192, end-of-life type, or a confidence level of RUL 127.

Clause 12. Method 200 of any one of clauses 1-11, further comprising filtering reference sensor data 116 by removing reference sensor outliers from a sensor data set, the sensor data set comprising reference sensor data 116.

Clause 13. Method 200 of any one of clauses 1-12, wherein reference sensor data 116 corresponds to RUL 127 of component 192 exceeding a certain minimum threshold.

Clause 14. Method 200 of any one of clauses 1-13, wherein vehicle 190 is a helicopter, and wherein component 192 is a nose gearbox.

Clause 15. Method of any one of clauses 1-14, further comprising performing at least one of, while vehicle 190 remains in service:

ordering one or more replacement parts for component 192 based on RUL 127, or

scheduling maintenance of vehicle 190 based on the RUL 127.

Clause 16. Method 200 of clause 15, wherein the ordering one or more replacement parts for component 192 based on RUL 127 or the scheduling maintenance of vehicle 190 based on RUL 127 is performed prior to any end of life of component 192.

Clause 17. Method 200 of any one of clauses 15-16, wherein frequency of the ordering one or more replacement parts for component 192 or scheduling maintenance of vehicle 190 varies and is determined based on RUL 127.

Clause 18. Method 200 of any one of clauses 1-17, wherein plurality of sensors 194 comprises one or more of an accelerometer, a temperature sensor, a pressure sensor, a voltmeter, an electrical current meter, and an acoustic sensor.

Clause 19. System 100 for determining RUL 127 of component 192 on vehicle 190 during operation of vehicle 190, system 100 comprising:

database 110, comprising reference sensor data 116, corresponding to component 192 of vehicle 190, wherein reference sensor data 116 is multidimensional; and

RUL module 120, communicatively coupled to database 110 and configured to obtain reference sensor data 116 from database 110,
RUL module 120 further configured to:
   obtain operational sensor data 196 from a plurality of sensors 194, operationally coupled to component 192 of the vehicle 190, wherein operational sensor data 196 is multidimensional,
   construct reference sensor data distribution 122, using reference sensor data 116,
   construct operational sensor data distribution 124, using operational sensor data 196,
   compute sliced-Wasserstein distances 125 between reference sensor data distribution 122 and operational sensor data distribution 124,
   determine ENS 126 based on sliced-Wasserstein distances 125, and
   determine RUL 127 of component 192 on vehicle 190 based on ENS 126 using RUL model 131.

Clause 20. A computer-readable medium including instructions 132, which when executed by RUL module 120, operably coupled to component 192 on vehicle 190 during operation of vehicle 190, cause RUL module 120, to perform operations, comprising:

obtaining reference sensor data 116, corresponding to component 192 of vehicle 190, wherein reference sensor data 116 is multidimensional;

obtaining operational sensor data 196 from plurality of sensors 194, operationally coupled to component 192 of vehicle 190, wherein operational sensor data 196 is multidimensional;

constructing reference sensor data distribution 122, using reference sensor data 116;

constructing operational sensor data distribution 124, using operational sensor data 196;

computing sliced-Wasserstein distances 125 between reference sensor data distribution 122 and operational sensor data distribution 124;

determining ENS 126 based on sliced-Wasserstein distances 125; and

determining RUL 127 of component 192 on vehicle 190 based on ENS 126 using RUL model 131.

### CONCLUSION

Although the foregoing concepts have been described in some detail for purposes of clarity of understanding, it will be apparent that certain changes and modifications may be practiced within the scope of the appended claims. It should be noted that there are many alternative ways of implementing the processes, systems, and apparatus. Accordingly, the present examples are to be considered as illustrative and not restrictive.

What is claimed is:

1. A method for continuously determining a remaining useful life (RUL) of a component on a vehicle during operation of the vehicle, the method comprising:
obtaining reference sensor data, corresponding to the component of the vehicle, wherein the reference sensor data is multidimensional;
obtaining operational sensor data from a plurality of sensors, operationally coupled to the component of the vehicle, wherein the operational sensor data is multidimensional;
constructing reference sensor data distribution, using the reference sensor data;
constructing operational sensor data distribution, using the operational sensor data;
computing sliced-Wasserstein distances between the reference sensor data distribution and the operational sensor data distribution;
determining early notification signals (ENS) based on the sliced-Wasserstein distances; and
determining the RUL of the component on the vehicle based on the ENS using a RUL model.

2. The method of claim 1, wherein determining the RUL of the component on the vehicle comprises:
dynamically developing multiple RUL models; and
selecting the RUL model from the multiple RUL models for determining the RUL of the component on the vehicle.

3. The method of claim 2, wherein selecting the RUL model is performed using permutative simulation.

4. The method of claim 2, wherein each of the multiple RUL models corresponds to a different one of multiple RUL intervals and a different one of multiple ENS intervals, and wherein each of the multiple RUL models has a corresponding one of precision values.

5. The method of claim 4, wherein the RUL model is selected based on highest of the precision values for the ENS, determined based on the sliced-Wasserstein distances and being within a corresponding one of the multiple ENS intervals.

6. The method of claim 4, wherein each of the precision values is determined using cross-validation of a corresponding one of the multiple RUL models.

7. The method of claim 1, further comprising determining correlation of the ENS and the RUL using a constraint function based on a normalized dot product, a mean error ratio, and a range variance.

8. The method of claim 1, wherein at least obtaining the operational sensor data, constructing the operational sensor data distribution, computing the sliced-Wasserstein distances, and determining the ENS is performed continuously.

9. The method of claim 1, wherein the operational sensor data is a fixed-size set of most recent sensor data.

10. The method of claim 1, wherein the sliced-Wasserstein distances are one-dimensional.

11. The method of claim 1, wherein the ENS comprises one or more of end-of-life time of the component, end-of-life type, or a confidence level of the RUL.

12. The method of claim 1, further comprising filtering the reference sensor data by removing reference sensor outliers from a sensor data set.

13. The method of claim 1, wherein the reference sensor data corresponds to the RUL of the component exceeding a certain minimum threshold.

14. The method of claim 1, wherein the vehicle is a helicopter, and wherein the component is a nose gearbox.

15. The method of claim 1, further comprising performing at least one of, while the vehicle remains in service:
ordering one or more replacement parts for the component based on the RUL, or
scheduling maintenance of the vehicle based on the RUL.

16. The method of claim 15, wherein ordering one or more replacement parts for the component based on the RUL or scheduling maintenance of the vehicle based on the RUL is performed prior to any end of life of the component.

17. The method of claim 15, wherein frequency of ordering one or more replacement parts for the component or scheduling maintenance of the vehicle varies.

18. The method of claim 1, wherein the plurality of sensors comprises one or more of an accelerometer, a temperature sensor, a pressure sensor, a voltmeter, an electrical current meter, and an acoustic sensor.

19. A system for determining a remaining useful life (RUL) of a component on a vehicle during operation of the vehicle, the system comprising:
a database, comprising reference sensor data, corresponding to the component of the vehicle, wherein the reference sensor data is multidimensional; and
a RUL module, communicatively coupled to the database and configured to obtain the reference sensor data from the database,
the RUL module further configured to:
obtain operational sensor data from a plurality of sensors, operationally coupled to the component of the vehicle, wherein the operational sensor data is multidimensional,
construct reference sensor data distribution, using the reference sensor data,
construct operational sensor data distribution, using the operational sensor data,
compute sliced-Wasserstein distances between the reference sensor data distribution and the operational sensor data distribution,
determine early notification signals (ENS) based on the sliced-Wasserstein distances, and
determine the RUL of the component on the vehicle based on the ENS using a RUL model.

20. A computer-readable medium including instructions, which when executed by a RUL module, operably coupled to a component on a vehicle during operation of the vehicle, cause the RUL module, to perform operations, comprising:
obtaining reference sensor data, corresponding to the component of the vehicle, wherein the reference sensor data is multidimensional;
obtaining operational sensor data from a plurality of sensors, operationally coupled to the component of the vehicle, wherein the operational sensor data is multidimensional;
constructing reference sensor data distribution, using the reference sensor data;
constructing operational sensor data distribution, using the operational sensor data;
computing sliced-Wasserstein distances between the reference sensor data distribution and the operational sensor data distribution;
determining early notification signals (ENS) based on the sliced-Wasserstein distances; and
determining the RUL of the component on the vehicle based on the ENS using a RUL model.
